(19) United States
(12) Patent Application Publication
(10) Pub. No.: US 2010/0096661 A1
(43) Pub. Date: Apr. 22, 2010

(54) LIGHT EMITTING DIODE MODULE

(75) Inventor: Min Sang LEE, Suwon (KR)

Correspondence Address: MCDERMOTT WILL & EMERY LLP, 600 13TH STREET, N.W., WASHINGTON, DC, 20005-3096, US

(73) Assignee: Samsung Electro-Mechanics Co., Ltd., Gyunggi-Do (KR)

(21) Appl. No.: 12/642,122

(22) Filed: Dec. 18, 2009

Related U.S. Application Data
(62) Division of application No. 11/644,951, filed on Dec. 26, 2006.

(30) Foreign Application Priority Data
Feb. 23, 2006 (KR) 10-2006-0017628

(51) Int. Cl. H01L 33/48

(52) U.S. Cl. 257/99; 257/E33.058

(57) ABSTRACT

Provided an LED module comprising a metallic thin film having a flexibility; a circuit pattern printed on the metallic thin film so as to be insulated from the metallic thin film; one or more LEDs mounted on the metallic thin film on which the circuit pattern is not formed; wire for electrically connecting the LED and the circuit pattern; and a fluorescent body formed on the LED.

### CROSS-REFERENCE TO RELATED APPLICATIONS

This application claims the benefit of Korean Patent Application No. 10-2006-0017628 filed with the Korean Intellectual Property Office on Feb. 23, 2006, the disclosure of which is incorporated herein by reference.

### BACKGROUND OF THE INVENTION

1. Field of the Invention

The present invention relates to a light emitting diode module which is applied to electric sign boards and display devices for displaying characters and the like by using light emitting diodes. By using the light emitting diode module having a flexibility, electric display can be performed on a curved surface as well as a flat surface.

2. Description of the Related Art

A light emitting diode (hereinafter, referred to as the LED) is a light emitting element which emits light when electric currents flow therein. When minority carriers are injected into the pn-junction surface of semiconductor, electrons are excited into higher energy level. When the electrons are stabilized, the energy owned by the electrons is emitted as electronic waves having a wavelength range of light.

Recently, as a semiconductor technology rapidly develops, it has become possible to manufacture high-brightness and high-quality LEDs. Further, as the implementation of blue and white diodes with high characteristics is realized, the application of the LEDs is extended as a display device and next-generation light source.

One or more LEDs are joined into a predetermined size, thereby forming an LED module. The LED module is used in various display devices and electric sign boards.

When conventional LED modules are manufactured, LEDs are inserted or mounted on a PCB (printed circuit board) and then are mounted on a main PCB. Alternately, LEDs are disposed and mounted on a PCB with a predetermined size, and a driver for controlling the LEDs is mounted, thereby manufacturing one module. Then, each module is fixed by an external case and is connected to the controller through a cable.

As such, the conventional LED module is formed to have a predetermined size by joining one or more LEDs. Then, the LED module can be applied to various display devices and electric sign boards. However, since the LED module is not formed in a flat or polygonal shape because of the PCB or external case, it is difficult to install the LED module on an edge, a corner, a post, curved glass or the like. That is, there is a limit in installing various display devices and electric sign boards to which the conventional LED modules are applied. Further, when such devices are installed in a curved surface, the overall display quality is degraded.

Further, since the conventional LED module is manufactured by joining one or more LEDs, heat generated from each LED needs to be effectively radiated outside.

Therefore, it is continuously required to develop a technique related to the LED module, which can enhance heat radiation efficiency of the LED module.

### SUMMARY OF THE INVENTION

An advantage of the present invention is that it provides an LED module in which one or more LEDs are mounted on a flexible and soft metallic thin film having a predetermined circuit pattern formed. The LED module can minimize a limit in installation place and enhance heat radiation efficiency.

Additional aspect and advantages of the present general inventive concept will be set forth in part in the description which follows and, in part, will be obvious from the description, or may be learned by practice of the general inventive concept.

According to an aspect of the invention, an LED module comprises a metallic thin film having a flexibility; a circuit pattern printed on the metallic thin film so as to be insulated from the metallic thin film; one or more LEDs mounted on the metallic thin film on which the circuit pattern is not formed; wire for electrically connecting the LED and the circuit pattern; and a fluorescent body formed on the LED.

According to another aspect of the invention, an LED module comprises a metallic thin film having a flexibility; a circuit pattern printed on the metallic thin film so as to be insulated from the metallic thin film; and one or more LED packages mounted on the metallic thin film so as to be electrically connected to the circuit pattern. The LED module further includes a lead frame formed of the LED package; a package formed of synthetic resin so as to house a portion of the lead frame therein; an LED mounted on the lead frame inside the package; and a molding material filled in the package so as to protect the LED.

According to a further aspect of the invention, the circuit pattern printed printed on the metallic thin film so as to be insulated from the metallic thin film includes a first metallic thin film having an insulating pattern formed in the same shape as the circuit pattern; a conductive film formed on the insulating pattern; and a second metallic thin film formed on the first metallic thin film so as to be insulated from the conductive film.

According to a still further aspect of the invention, the first and second metallic thin films are formed of any one of copper, aluminum, nickel, and an alloy thereof.

According to a still further aspect of the invention, the LED module further comprises a flexible heat sink formed on one surface of the metallic thin film on which the circuit pattern is not printed. The heat sink is formed of any one of copper, aluminum, nickel, and an alloy.

According to a still further aspect of the invention, the heat sink is plated on one surface of the metallic thin film by a plating method.

According to a still further aspect of the invention, the flexible metallic thin film further includes one or more holes formed on portions where the circuit pattern is not formed, the holes being formed so as to be spaced from each other at a predetermined distance.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic view illustrating the structure of an LED module according to a first embodiment of the invention;

FIG. 2 is a partially-extended view illustrating ‘A’ portion of FIG. 1;

FIG. 3 is a sectional view taken along III-III′ line of FIG. 2;

FIG. 4 is a diagram illustrating the structure of an LED module according to a first modification of the first embodiment;

FIG. 5 is a schematic view illustrating the structure of an LED module according to a second modification of the first embodiment;

FIG. 6 is a partially-extended view illustrating ‘B’ portion of FIG. 5;

FIG. 7 is a sectional view taken along VII-VII′ line of FIG. 6;

FIG. 8 is a sectional view illustrating the structure of an LED module according to a third modification of the first embodiment; and

FIG. 9 is a diagram illustrating the structure of an LED module according to a second embodiment.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, preferred embodiments of the present invention will be described in detail with reference to the accompanying drawings.

### First Embodiment

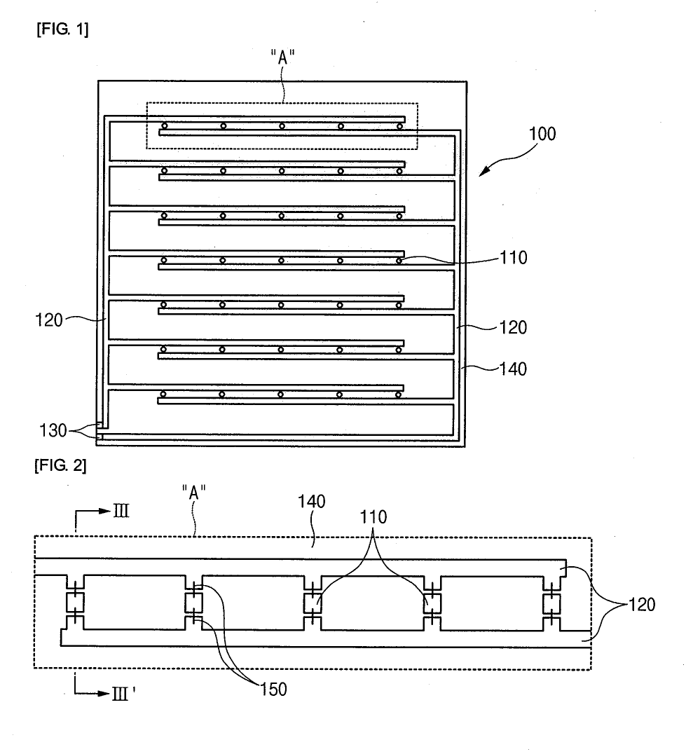

Hereinafter, an LED module according to a first embodiment of the invention will be described with reference to FIGS. 1 to 3.

FIG. 1 is a schematic view illustrating the structure of the LED module according to the first embodiment of the invention, and FIG. 2 is a partially-extended view illustrating ‘A’ portion of FIG. 1

Referring to FIGS. 1 and 2, the LED module 100 according to the first embodiment of the invention includes a metallic thin film 140 having a flexibility; a circuit pattern 120 which is printed on the metallic thin film 140 so as to be insulated therefrom; one or more LEDs 110 mounted on the metallic thin film 140 on which the circuit pattern 120 is not formed; and a fluorescent body (not shown) formed on the LED 110. The LED 110 and the circuit pattern 120 are electrically connected to each other through wire 150.

In FIG. 1, reference numeral 130 represents a power supply section for supplying power to the circuit pattern 120.

As such, the LED module 100 according to the invention is formed of a flexible metallic thin film 140, not a solid PCB forming a conventional LED module. Therefore, the LED module 100 can be installed on places having various curved surfaces, such as an edge, a corner, a post, curved glass and the like, without the overall display quality being degraded.

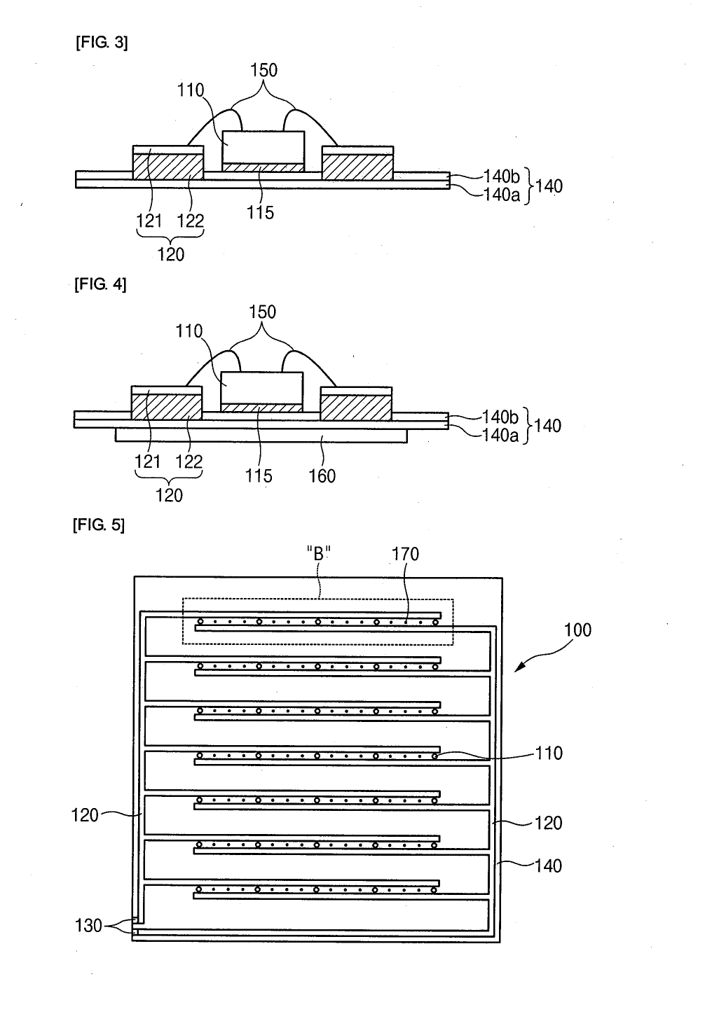

Hereinafter, referring to FIG. 3, the LED module according to the first embodiment will be described in more detail. FIG. 3 is a sectional view taken along III-III′ line of FIG. 2.

As shown in FIG. 3, the metallic thin film 140 includes a first metallic thin film 140a and a second metallic thin film 140b, which are sequentially laminated. Preferably, the first and second metallic thin films 140a and 140b are formed of any one of aluminum, nickel, and an alloy thereof, which have an outstanding heat radiation characteristic. Then, when the LED module is driven, heat generated by the respective LEDs 110 is easily radiated outside.

On the first metallic thin film 140a, a circuit pattern 120 for driving the LED module is formed so as to be insulated from the first metallic thin film 140a. More specifically, the circuit pattern 120 has an insulating pattern 122 formed at a predetermined height, the insulating pattern 122 being formed on the first metallic thin film 140a in the same shape as a circuit. On the insulating pattern 122, a conductive film 121 is formed. Accordingly, the conductive film 121 can be electrically insulated from the first metallic thin film 140a through the insulating pattern 122.

On the first thin film 140a, the second metallic thin film 140b is formed so as to be insulated from the conductive film 121 composing the circuit pattern 120.

Preferably, the second metallic thin film 140b according to the invention is formed of metal having high reflectance as well as an outstanding heat radiation characteristic. In such a structure, light emitted from the LED 110 mounted on the second metallic thin film 140b is prevented from being absorbed or diffused into the second metallic thin film 140b. The LED module according to the invention can enhance light efficiency as well as a heat radiation effect. Therefore, the brightness of various display devices and electric sign boards, to which the LED modules are applied, can be enhanced, thereby improving a display quality.

Preferably, the LED 100 mounted on the second metallic thin film 140b is fixed through a transparent bonding layer 115 with high heat conductivity.

The LED 110 fixed on the second metallic thin film 104b through the bonding layer 115 is electrically connected to the adjacent circuit patterns 120, that is, a pair of electrodes through the wire 150.

Hereinafter, modifications of the LED module according to the first embodiment of the invention will be described with reference to FIGS. 4 to 8. However, the descriptions of the same construction as the first embodiment will be omitted.

### First Modification

First, a first modification of the LED module according to the first embodiment of the invention will be described in detail with reference to FIG. 4. FIG. 4 is a diagram illustrating the structure of an LED module according to the first modification.

As shown in FIG. 4, the LED module according to the first modification has almost the same construction as the LED module according to the first embodiment. However, the LED module according to the first modification further includes a flexible heat sink 160 formed on one surface of the metallic thin film 140, on which the circuit pattern 120 is not printed.

Preferably, the heat sink 160 for enhancing heat radiation efficiency is formed of metal such as copper, aluminum, nickel, or an alloy thereof, which has an outstanding heat radiation characteristic.

The heat sink 160 can be bonded through a bonding layer (not shown) or can be formed by using a plating method.

Such a first modification can obtain the same operation and effect as the first embodiment. Further, since the first modification further includes the heat sink 160, heat generated by the LED 110 can be easily radiated outside by the heat sink 160, when the LED module is driven. Therefore, it is possible to obtain a more excellent heat radiation effect than in the first embodiment.

### Second Modification

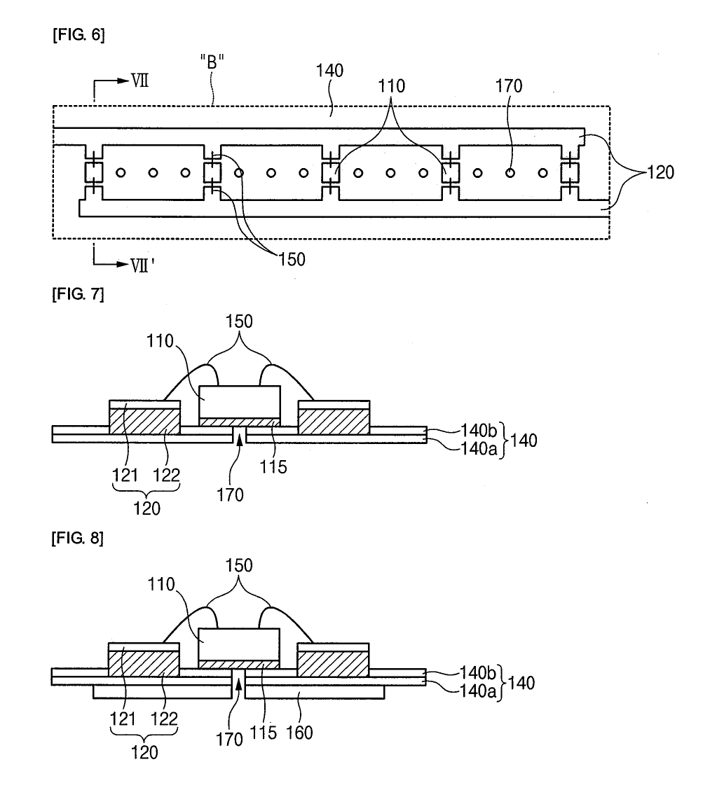

Referring to FIGS. 5 to 7, a second modification of the LED module according to the first embodiment of the invention will be described in detail. FIG. 5 is a schematic view illustrating the structure of an LED module according to the second modification. FIG. 6 is a partially extended view illustrating ‘B’ portion of FIG. 5. FIG. 7 is a sectional view taken along VII-VII' line of FIG. 6.

Referring to FIGS. 5 to 7, the LED module according to the second modification has almost the same construction as the LED module according to the first embodiment. However, the LED module according to the second modification further includes one or more holes 170 formed on portions of the flexible metallic thin film 140, on which the circuit pattern 120 is not formed. The holes 170 are formed so as to be spaced from each other at a determined distance.

FIG. 7 shows a state where the hole 170 is also formed on a portion on which the LED 110 is mounted. However, the hole 170 does not need to be formed thereon depending on the characteristics and the process condition of the LED.

In the LED module of the invention, the flexible metallic thin film further includes one or more holes 170 formed on portions on which the circuit pattern 120 is not formed, the holes 170 formed so as to be spaced from each other at a predetermined distance. Therefore, heat radiation efficiency is enhanced. In this case, the number of holes 170 and the distance therebetween can be changed in accordance with a process condition.

Such a second modification can obtain the same operation and effect as the first embodiment. Further, as in the first modification, heat generated by the LED 110 can be easily radiated outside by the holes 170, when the LED module is driven. Therefore, it is possible to obtain a more excellent heat radiation effect than in the first embodiment.

### Third Modification

Referring to FIG. 8, a third modification of the LED module according to the first embodiment of the invention will be described in detail. FIG. 8 is a sectional view illustrating the structure of an LED module according to the third modification.

As shown in FIG. 8, the LED module according to the third modification has almost the same construction as the LED module according to the first modification. However, the LED module according to the third modification further includes one or more holes 170 formed on portions of the flexible metallic thin film 140, on which the circuit pattern 120 is not formed. The holes 170 are formed so as to be spaced from each other at a determined distance.

Both of the metallic thin film 140 and the heat sink 160 have the hole 170. However, the hole 170 can be formed only in any one of the metallic thin film 140 and the heat sink 160, if necessary. That is, the number of holes, the distance therebetween, and the formation positions can be adjusted depending on a process condition of the LED module.

### Second Embodiment

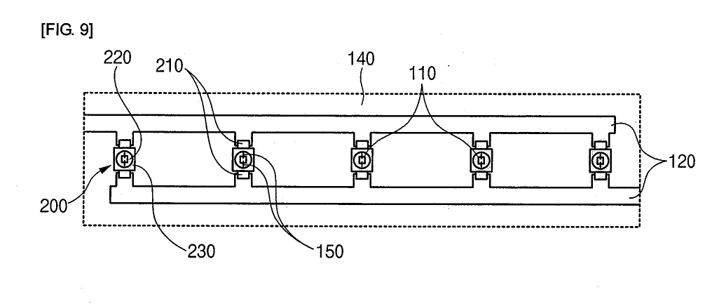

Referring to FIG. 9, an LED module according to a second embodiment of the invention will be described in detail. However, the descriptions of the same construction as the first embodiment will be omitted.

FIG. 9 is a diagram illustrating the structure of the LED module according to the second embodiment of the invention.

The LED module 100 according to the second embodiment of the invention has almost the same construction as the LED module according to the first embodiment. As shown in FIG. 9, however, the LED 110 mounted on the flexible metallic thin film 140 is not electrically connected to the circuit pattern 120 through the wire 150, but an LED package 200 is mounted on the metallic thin film 140 so as to be directly connected to the circuit pattern 120.

Preferably, the surface-mounted LED package 200 includes a lead frame 210 composed of a pair of lead terminals; a package 230 formed of synthetic resin so as to house a portion of the lead frame 210 therein; the LED 110 mounted on the lead frame 210 inside the package 230; and a molding material filled in the package 230 so as to protect the LED 110. The molding material 220 is formed of a fluorescent body having high color gamut.

As such, since the LED module according to the second embodiment includes the molding material 220 formed of a fluorescent body having high color gamut inside the surface-mounted LED package 200, the process can be simplified in comparison with the first embodiment in which a fluorescent body (not shown) should be separately formed on the metallic thin film 140 having the LED 100 mounted thereon. Therefore, pollution in a manufacturing process can be prevented, which makes it possible to enhance the reliability of the LED module.

In the second embodiment, the first to third modifications of the first embodiment can be applied, and the same operation and effect can be obtained.

According to the present invention, one or more LEDs are mounted on the flexible and soft metallic thin film on which a predetermined circuit pattern is formed, in order to form the LED module. Therefore, it is possible to minimize the limitation of place where various display devices and electric sign boards formed by using the LED module are installed.

Further, since the metallic thin film is formed of metal having excellent heat conductivity, the radiation efficiency of heat generated by the LED can be enhanced, thereby maximizing the life span of the LED module.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1-10. (canceled)

11. An LED module comprising:
a metallic thin film having a flexibility;
a circuit pattern printed on the metallic thin film so as to be insulated from the metallic thin film; and
one or more LED packages mounted on the metallic thin film so as to be electrically connected to the circuit pattern.

12. The LED module according to claim 11,
wherein the LED package includes:
a lead frame composed of a pair of lead terminals;
a package formed of synthetic resin so as to house a portion of the lead frame therein;
an LED mounted on the lead frame inside the package; and
a molding material filled in the package so as to protect the LED.
